(19) United States
(12) Patent Application Publication
(10) Pub. No.: US 2004/0013803 A1
(43) Pub. Date: Jan. 22, 2004

(54) Formation of titanium nitride films using a cyclical deposition process

(75) Inventors: Hua Chung, San Jose, CA (US); Hongbin Fang, Mountain View, CA (US); Ken K. Lai, Milpitas, CA (US); Jeong Soo Byun, Cupertino, CA (US); Alfred W. Mak, Union City, CA (US); Michael X. Yang, Fremont, CA (US); Ming Xi, Palo Alto, CA (US); Moris Kori, Palo Alto, CA (US); Xinliang Lu, Sunnyvale, CA (US); Ping Jian, San Jose, CA (US)

Correspondence Address: PATENT COUNSEL, APPLIED MATERIALS, INC., Legal Affairs Department, P.O. BOX 450A, Santa Clara, CA, 95052, US

(73) Assignee: Applied Materials, Inc.

(21) Appl. No.: 10/321,033

(22) Filed: Dec. 16, 2002

(30) Foreign Application Priority Data
Jul. 16, 2002 (WO) PCT/US02/22492

(51) Int. Cl. C23C 16/34; B32B 9/00

(52) U.S. Cl. 427/255.391; 427/255.394; 428/698

(57) ABSTRACT

Methods of depositing titanium nitride (TiN) films on a substrate are disclosed. The titanium nitride (TiN) films may be formed using a cyclical deposition process by alternately adsorbing a titanium-containing precursor and a NH₃ gas on the substrate. The titanium-containing precursor and the NH₃ gas react to form the titanium nitride (TiN) layer on the substrate. The titanium nitride (TiN) films are compatible with integrated circuit fabrication processes. In one integrated circuit fabrication process, an interconnect structure is fabricated. The titanium nitride films may also be used as an electrode of a three-dimensional capacitor structure such as for example, trench capacitors and crown capacitors.

### CROSS-REFERENCE TO RELATED APPLICATIONS

This application claims benefit of U.S. provisional patent application serial No. 60/305,646, filed Jul. 16, 2001, and PCT patent application serial No. PCT/US02/22492 filed Jul. 16, 2002, which is incorporated by reference in its entirety.

### BACKGROUND OF THE INVENTION

1. Field of the Invention

Embodiments of the present invention generally relate to methods of titanium nitride film formation and, more particularly to methods of titanium nitride film formation using a cyclical deposition technique.

2. Description of the Related Art

In the manufacture of integrated circuits, contact level metallization schemes are often used to provide low resistance contacts to an underlying semiconductor material. Typically, contact level metallization schemes combine a barrier layer with a contact level metal layer.

For example, when a metal contact structure is fabricated, a barrier layer (e.g., titanium nitride (TiN)) is formed between the underlying semiconductor material (e.g., polysilicon) and the contact level metal layer (e.g., tungsten (W), aluminum (Al) or copper (Cu)) of the gate electrode. The barrier layer inhibits the diffusion of the tungsten, aluminum or copper into the polysilicon material. Such tungsten, aluminum or copper diffusion is undesirable because it potentially changes the characteristics of the contact.

As circuit densities of integrated circuits increase, the widths of vias, lines and contacts may decrease to sub-micron dimensions (e.g., less than about 0.2 micrometers), whereas the thickness of the dielectric material layers between such structures typically remains relatively constant. This increases the aspect ratio (feature height divided by feature width) for such features. Many traditional deposition processes (e.g., chemical vapor deposition (CVD) and physical vapor deposition (PVD)) are not useful for filling sub-micron structures where the aspect ratio exceeds 6:1, and especially where the aspect ratio exceeds 10:1.

FIGS. 1A-1B illustrate the possible consequences of material layer deposition using conventional techniques in a high aspect ratio feature 6 formed on a substrate 1. The high aspect ratio feature 6 may be any opening such as a space formed between adjacent features 2, a contact, a via, or a trench defined in a layer 2. As shown in FIG. 1A, a material layer 11 that is deposited using conventional deposition techniques tends to be deposited on the top edges 6T of the feature 6 at a higher rate than at the bottom 6B or sides 6S thereof, creating an overhang. This overhang or excess deposition of material is sometimes referred to as crowning. Such excess material continues to build up on the top edges 6T of the feature 6, until the opening is closed off by the deposited material 11 forming a void therein. Additionally, as shown in FIG. 1B, a seam 8 may be formed when a material layer 11 deposited on both sides 6S of the opening merge. The presence of either voids or seams may result in unreliable integrated circuit performance.

Therefore, a need exists for a method of depositing titanium nitride (TiN) films in high aspect ratio openings.

### SUMMARY OF THE INVENTION

Methods of depositing titanium nitride (TiN) films on a substrate are provided. The titanium nitride (TiN) films are formed using a cyclical deposition process by alternately adsorbing a titanium-containing precursor and a nitrogen-containing gas on the substrate. The titanium-containing precursor and the nitrogen-containing gas react to form the titanium nitride (TiN) layer on the substrate. Thus, the a method of forming a TiN layer, comprising introducing a substrate into a process environment having a temperature of about 350° C. to about 650° C. and a pressure of about 3 torr to about 10 torr; establishing a carrier gas flow in the process environment; providing titanium tetrachloride to the process environment at a flow rate of 50-150 mg/ml for a duration of about 50 to about 150 milliseconds; adsorbing the titanium tetrachloride on the substrate; providing ammonia gas to the process environment at a flow rate of about 300 sccm to about 2000 sccm for a duration of about 50 to about 250 milliseconds; adsorbing the ammonia gas onto the substrate, wherein a TiN film is formed on the substrate; and repeating the providing and adsorbing steps until a desired thickness of the TiN film is formed.

### BRIEF DESCRIPTION OF THE DRAWINGS

So that the manner in which the above recited features of the present invention can be understood in detail, a more particular description of the invention, briefly summarized above, may be had by reference to the embodiments that are disclosed in this specification and illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1B are cross-sectional views of possible deposition results for high aspect ratio features filled using conventional prior art deposition processes;

FIGS. 2A-2B are drawings of exemplary embodiments of a processing system that may be used to perform cyclical deposition;

FIG. 3 illustrates a process sequence for titanium nitride (TiN) layer formation using cyclical deposition techniques according to one embodiment described herein;

FIG. 4 illustrates a process sequence for titanium nitride (TiN) layer formation using cyclical deposition techniques according to an alternate embodiment described herein;

FIG. 5 is a graph of the titanium nitride (TiN) film resistivity plotted as a function of heater temperature for TiN films deposited by both cyclical deposition and by chemical vapor deposition;

FIG. 6 is a graph of the titanium nitride (TiN) film chlorine content plotted as a function of heater temperature for TiN films deposited by both cyclical deposition and by chemical vapor deposition;

FIGS. 7A-7C illustrate schematic cross-sectional views of an integrated circuit at different stages of an interconnect fabrication process; and

FIGS. 8A-8B illustrate schematic cross-sectional views of an integrated circuit at different stages of a trench capacitor fabrication sequence.

### DETAILED DESCRIPTION

Deposition System

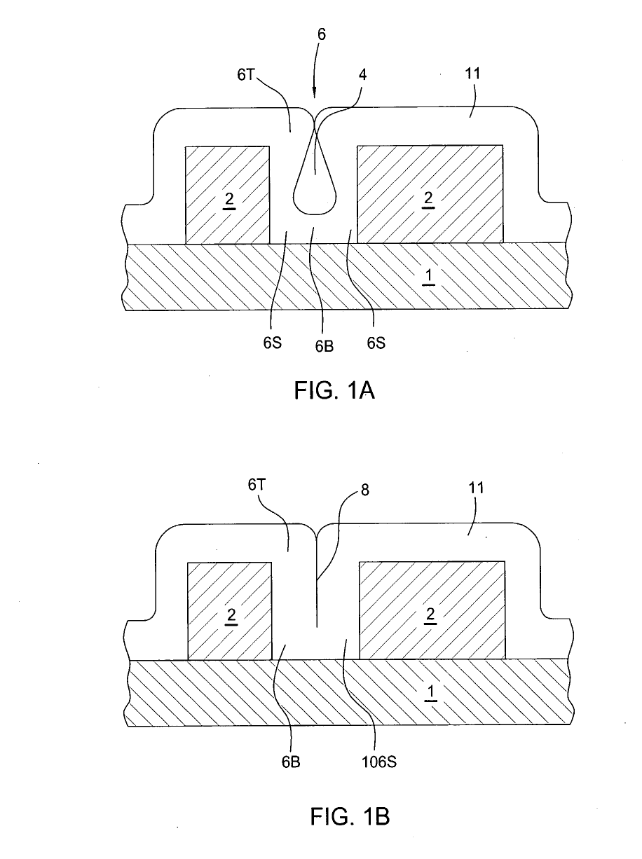

FIG. 1 is a perspective view of a processing system 100 having one or more isolated zones/flow paths to deliver one or more process gases to a workpiece/substrate surface disposed therein. The isolated zones/flow paths prevent exposure or contact of the precursor gases prior to deposition on the substrate surface. Otherwise, the highly reactive precursor gases may mix and form unwanted deposits within the processing system 100. Accordingly, the isolated zones/flow paths allow greater production throughput since less down time is required for cleaning the processing system 100. The isolated zones/flow paths also provide a more consistent and repeatable deposition process. The term “process gas” is intended to include one or more reactive gas, precursor gas, purge gas, carrier gas, as wells as a mixture or mixtures thereof.

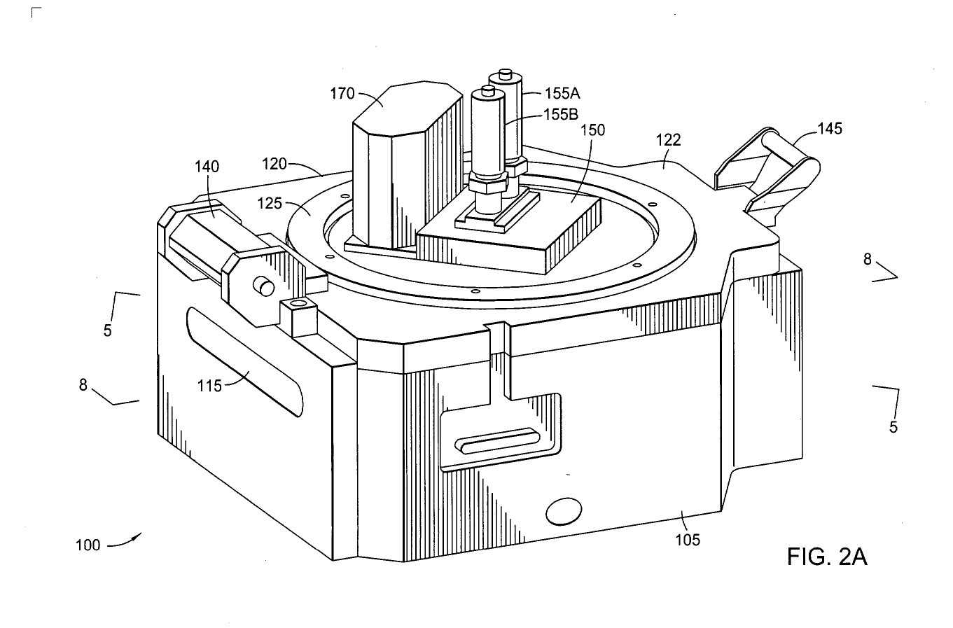

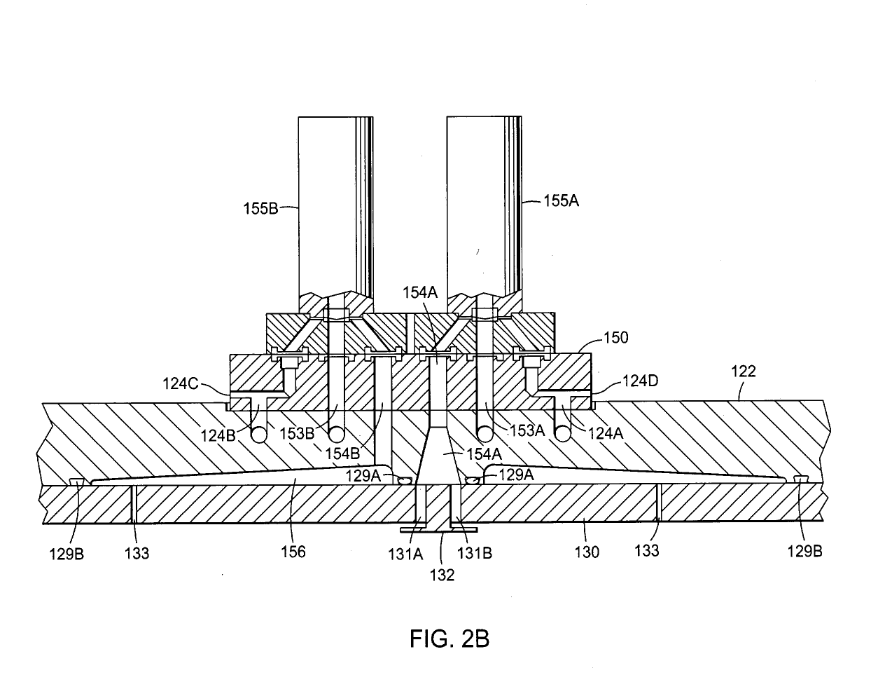

The processing system 100 includes a lid assembly 120 disposed on an upper surface of a chamber body 105 that form a fluid-tight seal there-between in a closed position. The lid assembly 120 includes a lid plate 122, a ring heater 125, a manifold block 150, one or more reservoirs 170, and a distribution plate 130 (shown in FIG. 2). The lid assembly 120 also includes one or more valves, preferably two high-speed valves 155A, 155B. The processing system 100 and the associated hardware are preferably formed from one or more process-compatible materials, such as aluminum, anodized aluminum, nickel plated aluminum, nickel plated aluminum 6061-T6, stainless steel, as well as combinations and alloys thereof, for example.

The ring heater 125, manifold block 150, and the one or more reservoirs 170 are each disposed on an upper surface of the lid plate 122. The one or more valves 155A, 155B are mounted on an upper surface of the manifold block 150. A handle 145 is disposed at one end of the lid plate 122, and a hinge assembly 140 is disposed at an opposite end of the lid plate 122. The hinge assembly 140 is connectable to the chamber body 105 and together with the handle 145 assists in the removal of the lid assembly 120, providing access to an interior of the chamber body 105. A workpiece (not shown) to be processed is disposed within the interior of the chamber body 105.

The ring heater 125 is disposed on an outer surface of the lid plate 122 to increase the surface temperature of the lid plate 122. The ring heater 125 may be attached to the lid plate 120 using one or more fasteners, such as screws or bolts, for example. In one aspect, the ring heater 125 may house one or more electrically resistive coils or heating elements (not shown). The ring heater 125 controls the temperature of the lid plate 122 to prevent the formation of unwanted adducts or by-products of the process gases. Preferably, the temperature of the lid plate 122 is maintained above 90° C.

The manifold block 150 includes one or more cooling channels (not shown) disposed therein to remove heat transferred from the lid plate 122 as well as any heat generated from the high speed actuation of the valves 155A, 155B. The cooling effect provided by the manifold block 150 protects the valves 155A, 155B from early failure due to excessive operating temperatures and thus, promotes the longevity of the valves 155A, 155B. Yet, the cooling effect is controlled so as not to condense the process gas or otherwise interfere with the energy output of the ring heater 125. Preferably, the cooling channels (not shown) utilize cooling water as the heat transfer medium and are disposed about a perimeter of the manifold block 150.

The upper surface of the manifold block 150 is also coextensive with a lower surface of the valves 155A, 155B. For example, the coextensive surfaces may be milled to represent a w-shape, c-shape, or any other shape capable of providing a conformal, coextensive seal. A gasket (not shown) made of stainless steel or any other compressible and process compatible material, may be placed between the two coextensive surfaces and compressed to provide a fluid tight seal there-between.

The one or more reservoirs 170 each provide bulk fluid delivery to the respective valves 155A, 155B. Preferably, the lid assembly 120 includes one reservoir 170 for each process gas. In one aspect, the lid assembly 120 includes at least two reservoirs for a process gas. Each reservoir 170 contains between about 2 times the required volume and about 20 times the required volume of a fluid delivery cycle provided by the high speed valves 155A, 155B. The one or more reservoirs 170, therefore, insure a required fluid volume is always available to the valves 155A, 155B.

The valves 155A, 155B are high speed actuating valves having two or more ports. For example, the valves 155A, 155B may be electronically controlled (EC) valves, which are commercially available from Fujikin of Japan as part number FR-21-6.35 UGF—APD. The valves 155A, 155B precisely and repeatedly deliver short pulses of process gases into the chamber body 105. The valves 155A, 155B can be directly controlled by a system computer, such as a mainframe for example, or controlled by a chamber/application specific controller, such as a programmable logic computer (PLC) which is described in more detail in the co-pending U.S. patent application entitled “Valve Control System For ALD Chamber”, Ser. No. 09/800,881, filed on Mar. 7, 2001, which is incorporated by reference herein. The on/off cycles or pulses of the valves 155A, 155B are less than about 75 msec. In one aspect, the valves 155A, 155B are three-way valves tied to both a precursor gas source and a continuous purge gas source. As will be explained in more detail below, each valve 155A, 155B meters a precursor gas while a purge gas continuously flows through the valve 155A, 155B.

Considering the one or more isolated zones/flow paths in more detail, FIG. 2 shows a partial cross section of the lid assembly 120. Each isolated zone/flow path is formed throughout the lid assembly 120 and the chamber body 105. Each zone/flow path contains one or more process gases flowing there-through. In one aspect, at least one zone/flow path delivers more than one process gas to the chamber body 105. For ease and simplicity of description, however, embodiments of the invention will be further described in terms of a two precursor gas deposition system. For a two precursor gas system, the processing system 100 will include at least two isolated zones/flow paths formed there-through. Each flow path, namely a first flow path and a second flow path, delivers its respective process gas to the workpiece surface within the chamber body 105.

The distribution plate 130 is disposed on a lower surface of the lid plate 122. The distribution plate 130 includes a plurality of apertures 133 surrounding one or more centrally located openings, preferably two openings 131A, 131B. FIG. 2A is an enlarged view of an upper surface of the distributor plate 130 illustrating the plurality of apertures 133 disposed about the openings 131A, 131B.

A process gas flowing through the first flow path enters the chamber body 105 and contacts the workpiece surface via the centrally located openings 131A, 131B. Although the openings 131A, 131B are shown as being circular or rounded, the openings 131A, 131B may be square, rectangular, or any other shape. A process gas flowing through the second flow path enters the chamber body 105 and contacts the workpiece surface via the plurality of apertures 133. The apertures 133 are sized and positioned about the distribution plate 130 to provide a controlled and even flow distribution across the surface of the workpiece.

A portion of the lower surface of the lid plate 122 is recessed so that a sealed cavity 156 is formed between the lid plate 122 and the distribution plate 130 when the distribution plate 130 is disposed on the lid plate 122. The apertures 133 of the distribution plate 130 are aligned within the cavity 156 so that the process gas flowing through the second flow path fills the cavity 156 and then evenly distributes within the chamber body 105 via the apertures 133.

The first and second flow paths are isolated at the distribution plate 130 by one or more o-ring type seals disposed on a lower surface of the lid plate 122. The lower surface of the lid plate 122 includes one or more concentric channels, preferably two channels 129A, 129B, formed therein to house an elastomeric seal. The elastomeric seal forms an o-ring type seal and can be made of any process compatible material, such as a plastic, elastomer, or the like, which is capable of providing a fluid, tight seal between the distribution plate 130 and the lid plate 122.

In one aspect, an inner-most channel 129A is formed about the centrally located openings 131A, 131B, and an outer-most channel 129B is formed near an outer diameter of the distribution plate 130, surrounding the cavity 156. The first flow path is contained by the inner-most o-ring 129A, and the second flow path is contained by the outer-most o-ring 129B. Accordingly, the first and second flow paths are isolated from each other by the inner-most o-ring 129A, and the outer-most o-ring 129B contains the second flow path within the diameter of the distribution plate 130.

In another aspect, a plurality of additional channels are formed within the lid plate 122 and are located between the inner-most channel 129A and the outer-most channel 129B. Each additional channel forms an additional, isolated zone/flow path through the distribution plate 130.

A dispersion plate 132 is also disposed within a portion of the first flow path. The dispersion plate 132 is disposed on a lower surface of the distribution plate 130, adjacent an outlet of the openings 131A, 131B. The distribution plate 130 and dispersion plate 132 may be milled from a single piece of material, or the two components may be milled separately and affixed together. The dispersion plate 132 prevents the process gas flowing through the first flow path from impinging directly on the workpiece surface by slowing and re-directing the velocity profile of the flowing gases.

Although various orientations of the workpiece are envisioned, the workpiece is preferably disposed horizontally or substantially horizontally within the chamber body 105. Accordingly, the process gas exiting the openings 131A, 131B flows substantially orthogonal to the workpiece surface. The dispersion plate 132, therefore, re-directs the substantially orthogonal velocity profile into an at least partially, non-orthogonal velocity profile. In other words, the dispersion plate 132 causes the process gas to flow radially outward, both vertically and horizontally, toward the workpiece surface there-below. Preferably, a cross-sectional area of the dispersion plate 132 is large enough to substantially reduce the kinetic energy of the process gas passing through the openings 129A, 129B. However, the cross-sectional area of the dispersion plate 132 is small enough so not to prevent deposition on the workpiece surface directly in line with the openings 131A, 131B.

The re-directed flow resembles an inverted v-shape and provides an even flow distribution across the workpiece surface. The increased cross sectional area provided by the inverted v-shape decreases the velocity of the process gas thereby reducing the force directed on the workpiece surface. Without this re-direction, the force asserted on the workpiece by the process gas can prevent deposition because the kinetic energy of the impinging process gas can sweep away reactive molecules already disposed on the workpiece surface. Accordingly, retarding and re-directing the process gas in a direction at least partially, non-orthogonal to the workpiece surface provides a more uniform and consistent deposition.

Still referring to FIG. 2, the first flow path further includes an inlet precursor gas channel 153A, an inlet purge gas channels 124A, the valve 155A, and an outlet process gas channel 154A that is in fluid communication with the openings 131A, 131B described above. Similarly, the second flow path further includes an inlet precursor gas channel 153B, an inlet purge gas channels 124B, the valve 155B, and an outlet process gas channel 154B that is in fluid communication with the apertures 133 described above. The inlet precursor gas channels 153A, 153B, the inlet purge gas channels 124A, 124B, and the outlet process gas channels 154A, 154B are formed within the lid plate 122 and the manifold block 150. The inlet precursor channels 153A, 153B are each connectable to a process gas source (not shown) at a first end thereof and connectable to the respective valve 155A, 155B at a second end thereof. The inlet purge gas channels 124A, 124B transfer one or more purge gases from their sources (not shown) to the respective valve 155A, 155B. The outlet gas channel 154B is connectable to the second valve 155B at a first end thereof and feeds into the chamber body 105 at a second end thereof via the cavity 156. The outlet gas channel 154A is connectable to the first valve 155A at a first end thereof and feeds into the chamber body 105 at a second end thereof via the openings 131A, 131B. An inner diameter of the gas channel 154A gradually increases within the lid plate 122. The inner diameter increases to mate or match the outer diameter of the openings 131A, 131B. The inner diameter also increases so that the velocity of the process gas is substantially decreased. The increased diameter of the gas channel 154A in addition to the dispersion plate 132 substantially decrease the kinetic energy of the process gas within the first flow path and thus, substantially improve deposition on the workpiece surface there-below.

Titanium Nitride Layer Formation

Methods of titanium nitride (TiN) layer formation are described. The titanium nitride (TiN) layer is formed using a cyclical deposition process by alternately adsorbing a titanium-containing precursor and a nitrogen-containing gas on a substrate. Titanium nitride is currently used as the metal electrode in metal-insulator-semiconductor stack capacitors and as a contact barrier. In the past, chemical vapor deposition of TiN films using TiCl₄ and NH₃ precursors was developed and used for these applications. However, process integration of sub-0.13 μm generation stack capacitors and deep trench contacts requires improved process results. Results obtained by the methods of the present invention include better step coverage on high aspect-ratio structures, lower process temperatures, lower chlorine content in the resulting film, lower resistivity of the resulting film and lower capacitor leakage current. CVD of TiCl₄ TiN films is limited to heater termperatures greater than 600° C. At lower wafer temperatures, CVD deposition cannot achieve low film resistivity (<200 μΩ cm) or low chlorine content (<1%). Further, step coverage of CVD TiCl₄ TiN films generally is poor (<20%) on aggressive structures (top openings approximately 0.20 mm and aspect ratios of 30-50).

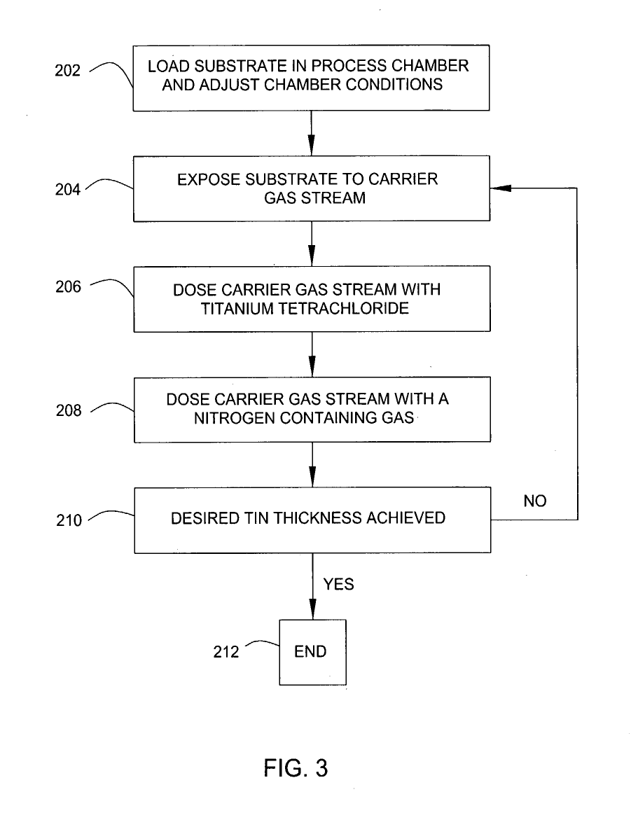

FIG. 3 illustrates one embodiment of a process sequence 200 for titanium nitride (TiN) layer formation utilizing a constant carrier gas flow. These steps may be performed in a process chamber similar to that described supra with reference to FIGS. 2A-2B. As shown in step 202, a substrate is introduced into the process chamber. The substrate may be for example, a silicon substrate ready for a copper metallization process sequence. The process chamber conditions, such as, for example, the temperature and pressure are adjusted to enhance the adsorption of process gases on the substrate. In general, for titanium nitride (TiN) layer deposition, the substrate should be maintained at a temperature at about 350-650° C., preferably at about 450-550° C., and at a process chamber pressure of above about 3 torr and less than about 10 torr, preferably about 5 torr.

In one embodiment where a constant carrier gas flow is desired, a carrier gas stream is established within the process chamber as indicated in step 204. Carrier gases may be selected so as to also act as a purge gas for removal of volatile reactants and/or by-products from the process chamber. Carrier gases such as, for example, helium (He), argon (Ar), hydrogen (H₂) and nitrogen (N₂), as well as combinations thereof, among others may be used. The carrier gas is established at a flow rate of about 300 sccm to about 3000 sccm in the chamber. In addition, gas flows at the substrate edge and chamber bottom may be established.

Referring to step 206, after the carrier gas stream is established within the process chamber, a pulse of titanium-containing precursor, TiCl₄ (titanium tetrachloride), is added to the carrier gas stream. The term pulse as used herein refers to a dose of material injected into the process chamber or into the constant carrier gas stream. The pulse of the TiCl₄ lasts for a time interval of at least 50-150 milliseconds when using a 50-150 mg/ml flow rate. The time interval for the pulse of the TiCl₄ is variable, however, depending upon a number of factors such as, for example, the flow rate of the TiCl₄, the volume capacity of the process chamber, the vacuum system coupled thereto and the temperature and pressure of the process chamber. In general, the process conditions are advantageously selected so that a pulse of the TiCl₄ provides a sufficient amount of precursor such that at least a monolayer of the TiCl₄ is adsorbed on the substrate. Thereafter, excess TiCl₄ remaining in the chamber is removed from the process chamber by the constant carrier gas stream in combination with the vacuum system.

In step 208, after the excess TiCl₄ sufficiently has been removed from the process chamber by the constant carrier gas stream to prevent co-reaction or particle formation with a subsequently provided process gas, a pulse of NH₃ (ammonia) gas is added to the carrier gas stream. The pulse of the NH₃ gas lasts for a time interval that is variable. The flow rate for the NH₃ gas may be about 300 sccm to 2000 sccm, preferably about 400 sccm to about 1000 sccm, and more preferably about 500 sccm to 700 sccm. In general, the time interval for the pulse of the NH₃ gas should be long enough for adsorption of at least a monolayer of the NH₃ gas on the TiCl₄. As with the TiCl₄ pulse, time for the NH₃ gas pulse will vary with factors such as, for example, the flow rate of the NH₃, the volume capacity of the process chamber, the vacuum system coupled thereto and the temperature and pressure of the process chamber. Pulse times for the NH₃ gas are generally greater than about 50 milliseconds and may last up to about 250 milliseconds or more, are preferably about 100 to about 150 milliseconds in duration, and are more preferably about 125 milliseconds in duration. After the NH₃ pulse, excess NH₃ gas remaining in the chamber is removed by the constant carrier gas stream in combination with the vacuum system.

Steps 204 through 208 comprise one embodiment of a deposition cycle for the titanium nitride (TiN) layer. For such an embodiment, a constant flow of the carrier gas is provided to the process chamber modulated by alternating periods of pulsing and non-pulsing where the periods of pulsing alternate between the TiCl₄ and the NH₃ gas along with the carrier gas stream, while the periods of non-pulsing include only the carrier gas stream.

The time interval for each of the pulses of the TiCl₄ and the NH₃ gas may have the same duration. Alternatively, the time interval for at least one of the pulse of the TiCl₄ and the NH₃ gas may have different durations. In addition, the periods of non-pulsing after each of the pulses of the TiCl₄ and the NH₃ gas may have the same duration or different durations.

Referring to step 210, after each deposition cycle (steps 204 through 208) a thickness of the titanium nitride will be formed on the substrate. Depending on specific device requirements, subsequent deposition cycles may be needed to achieve a desired thickness. As such, steps 204 through 208 are repeated until the desired thickness for the titanium nitride (TiN) layer is achieved. Thereafter, when the desired thickness for the titanium nitride (TiN) layer is achieved the process is stopped as indicated by step 212.

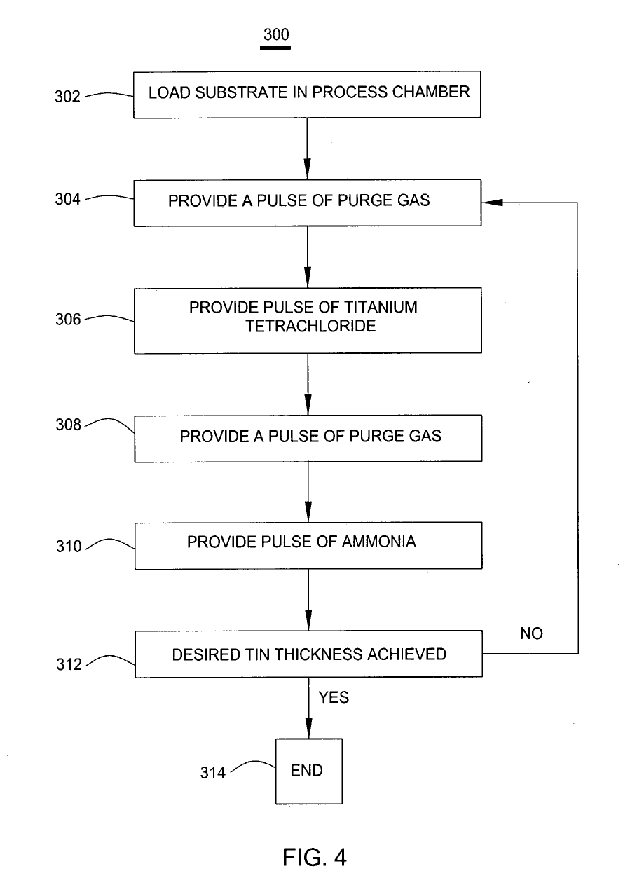

In an alternative process sequence described with respect to FIG. 4, the titanium nitride layer deposition cycle comprises separate pulses for each of the TiCl₄, the NH₃ gas and a purge gas. The purge gas generally comprises helium (He), argon (Ar), hydrogen (H₂) and nitrogen (N₂), as well as combinations thereof. The purge gas can be the same as, or different from, the carrier gas. As with the conditions for the pulses of the TiCl₄ and the NH₃ gas, the flow rate and pulse duration for the purge gas will vary depending on factors such as, for example, the flow rate of the purge and/or carrier gases, the volume capacity of the process chamber, the vacuum system coupled thereto and the temperature and pressure of the process chamber. Purge gas flow generally is about 250 sccm to about 3000 sccm, and preferably about 500 sccm to about 2500 sccm.

For this embodiment, the titanium nitride (TiN) deposition sequence 300 includes introducing the substrate into the process chamber and adjusting the process conditions (step 302), providing a pulse of a purge gas to the process chamber (step 304), providing a pulse of a TiCl₄ to the process chamber (step 306), providing a pulse of the purge gas to the process chamber (step 308), providing a pulse of a NH₃ gas to the process chamber (step 310), and then repeating steps 304 through 310, or stopping the deposition process (step 314) depending on whether a desired thickness for the titanium nitride (TiN) layer has been achieved (step 312). The time intervals for each of the pulses of the TiCl₄, the NH₃ gas, and the purge gas may have the same or different durations at various points in the cycle.

In FIGS. 3-4, the titanium nitride (TiN) layer deposition cycle is depicted as beginning with a pulse of the TiCl₄ followed by a pulse of a NH₃ gas. Alternatively, the titanium nitride (TiN) layer deposition cycle may start with a pulse of the NH₃ gas followed by a pulse of the TiCl₄. Additionally, a pulse may be one sustained injection of a precursor or gas, or maybe several sequential injections.

### EXAMPLE

The cylical deposition process of depositing a titanium nitride (TiN) layer according to the methods of the present invention overcomes the limitations of CVD of TiCl₄ TiN. Compared to CVD of TiCl₄ TiN films, cyclical deposition yields significant improvements, such as low film resistivity (≦150 μΩ cm), reduced chlorine content (≦1%), improved step coverage (≧90%) and reduced reaction temperature (450-550° C.), and reduced temperature sensitivity.

A carrier gas is provided throughout the deposition process. An argon or helium carrier flow is established in the deposition chamber at about 600 sccm. Additional chamber conditions may include an argon or helium edge flow of 500-1000 sccm and a bottom purge of 1000-7500 sccm. For the TiCl₄ pulse, TiCl₄ is provided to an appropriate control valve, such as the electronic control valve described supra, at a flow rate of 100 mg/min, and a pulse duration of 75 milliseconds. Thereafter, an argon or helium purge is provided to a control valve at about 500 sccm for 100-300 milliseconds. NH₃ gas is then pulsed into the chamber (using a control valve) at about 600 sccm for 125 milliseconds, followed by another argon or helium purge (2500 sccm for 100-300 milliseconds). A total cycle time of as little as 400 milliseconds may be obtained in this embodiment.

The cycling process continues until a desired film thickness is achieved. The specific embodiment described in this example deposits approximately 0.26 Å of TiN per cycle. Thus, for a 50 Å film, approximately 200 cycles are performed. For a 200 Å film, approximately 770 cycles are performed.

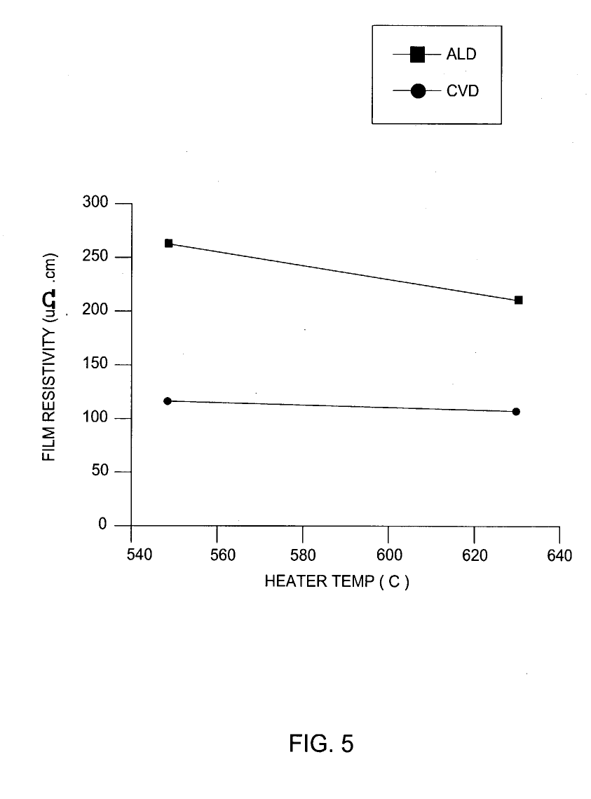

The resistivity of cyclically-deposited TiCl₄ TiN films is significantly lower than CVD TiCl₄ TiN films at heater temperatures of <650° C. FIG. 5 shows two plots of film resistivity versus heater temperature for film thicknesses of about 300 Å. With the CVD film (squares), the resistivity is approximately 200 μΩ-cm at a heater temperature of 630° C., and increases up to 250 μΩ-cm at about 550° C. With the cyclical deposition technique of the present invention (circles), the film resistivity is less than 150 μΩ-cm at temperature of 540 to 640° C.

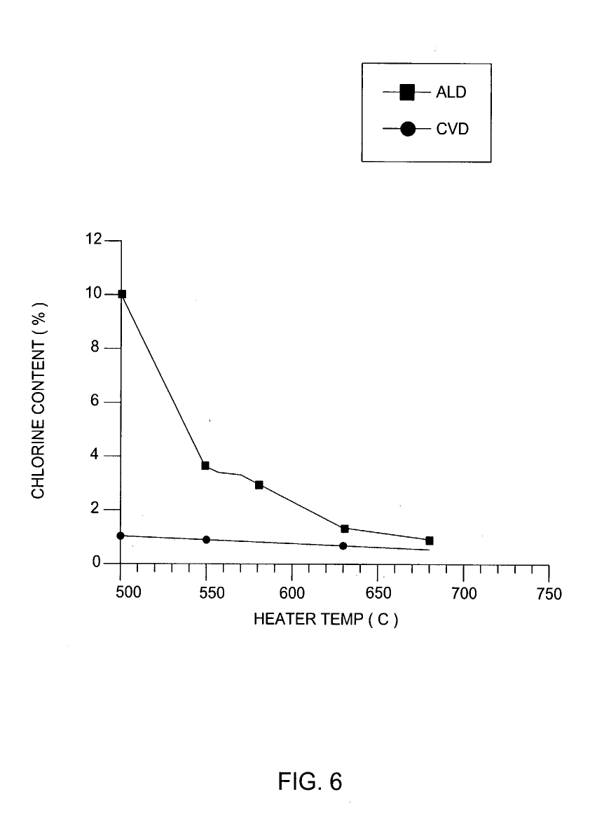

FIG. 6 shows the chlorine concentration of cyclically-deposited and CVD films versus heater temperature. With CVD, the chlorine concentration is >1%, and increases up to 10% at 500° C. With cyclical deposition, chlorine concentration is ≦1% at all tested heater temperatures down to 500° C. Thus, the cyclical deposition process results in excellent low chlorine content, even at lower deposition temperatures.

In addition, step coverage markedly is better for the cyclical deposition methods of the present invention than for CVD. Adequate exposure times for the TiCl₄ and NH₃ precursors (in this case 75 and 125 milliseconds, respectively) allow for saturation of surface reactions, even for aggressive structures, resulting in excellent step coverage. Scanning electron micrograph images of step coverage for both cyclical deposition and CVD on aggressive 0.13 to 0.23 mm×7.25 mm vias (aspect ratios of 30-50) were obtained. For the cyclical deposition process, step coverage was about 90%, whereas for CVD, step coverage was less than 20%.

Integrated Circuit Fabrication Process

1. Copper Interconnects

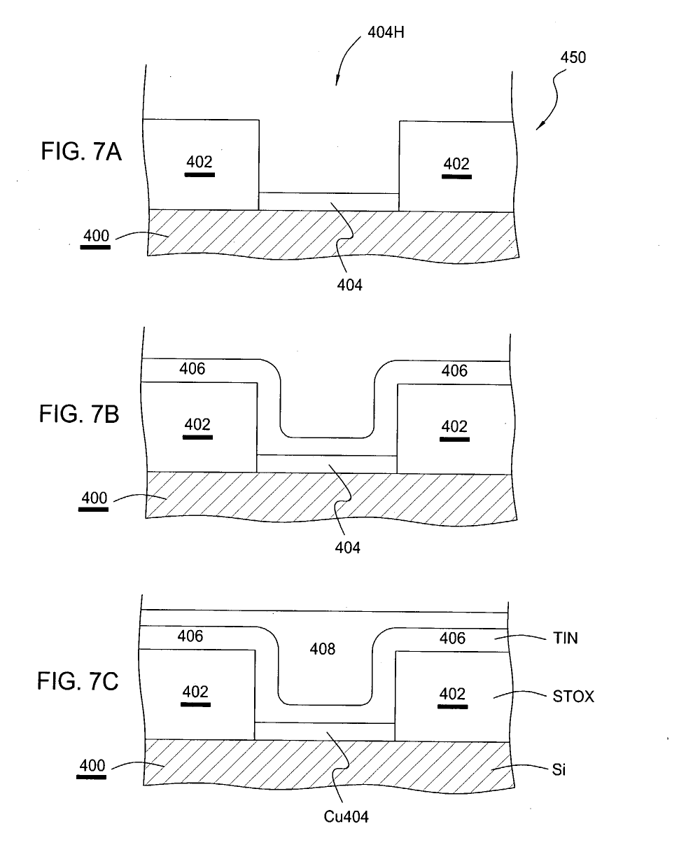

FIGS. 7A-7C illustrate cross-sectional views of a substrate at different stages of a copper interconnect fabrication sequence incorporating the titanium nitride (TiN) barrier layer of the present invention. FIG. 7A, for example, illustrates a cross-sectional view of a substrate 400 having metal contacts 404 and a dielectric layer 402 formed thereon.

The substrate 400 may comprise a semiconductor material such as, for example, silicon (Si), germanium (Ge), or gallium arsenide (GaAs). The dielectric layer 402 may comprise an insulating material such as, for example, silicon oxide or silicon nitride. The metal contacts 404 may comprise for example, copper (Cu).

Apertures 404H may be defined in the dielectric layer 402 to provide openings over the metal contacts 404. The apertures 404H may be defined in the dielectric layer 402 using conventional lithography and etching techniques.

Referring to FIG. 7B, a titanium nitride (TiN) barrier layer 406 is formed in the apertures 404H defined in the dielectric layer 402. The titanium nitride (TiN) barrier layer 406 is formed using the deposition techniques described above with respect to FIGS. 3-4.

The thickness of the titanium nitride (TiN) layer 406 is preferably thick enough to form a conformal layer when a porous material such as, for example, silicon oxides (e.g., SiO, SiO₂) is used for the dielectric material. The thickness of the titanium nitride (TiN) layer 406 is typically between about 20 Å to about 500 Å.

Thereafter, the apertures 404H are filled with copper (Cu) metallization 408 using a suitable deposition process as shown in FIG. 7C. For example, copper (Cu) may be deposited with a chemical vapor deposition (CVD) process using copper-containing precursors such as Cu⁺²(hfac)₂ (copper hexafluoro acetylacetonate), Cu⁺²(fod)₂ (copper heptafluoro dimethyl octanediene) and Cu⁺¹hfac TMVS (copper hexafluoro acetylacetonate trimethylvinylsilane), among others.

2. Trench Capacitors

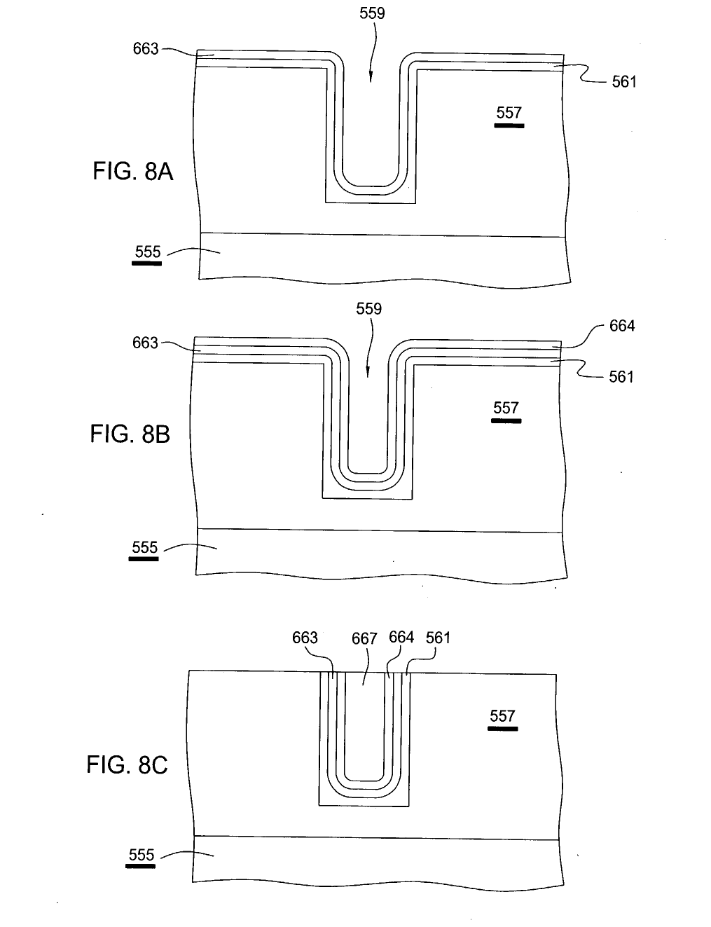

FIGS. 8A-8B are illustrative of a metal-insulator-metal (MIM) trench capacitor fabrication sequence incorporating a titanium nitride electrode of the present invention. FIG. 8A, for example, illustrates a cross-sectional view of a substrate 555 having a dielectric material layer 557 formed thereon. The substrate 555 may comprise a semiconductor material such as, for example, silicon (Si), germanium (Ge), or gallium arsenide (GaAs). The dielectric material layer 557 may comprise an insulator such as, for example, silicon oxide or silicon nitride. At least one trench 559 is defined in the dielectric material layer 557. The trench may be formed using conventional lithography and etching techniques.

A first electrode 661 is formed in the trench. The first electrode 661 comprises the first electrode of the metal-insulator-metal (MIM) trench capacitor. A suitable metal for the first electrode 661 includes, for example, tungsten (W). The thickness of the first electrode 661 is typically about 100 Å to about 1000 Å.

The trench capacitor further includes an insulating layer 663 formed over the first electrode 661. The insulating layer 663 preferably comprises a high dielectric constant material (dielectric constant greater then about 10). High dielectric constant materials advantageously permit higher charge storage capacities for the capacitor structures. Suitable dielectric materials may include for example, tantalum pentoxide (Ta₂O₅), silicon oxide/silicon nitride/oxynitride (ONO), aluminum oxide (Al₂O₃), barium strontium titanate (BST), barium titanate, lead zirconate titanate (PZT), lead lanthanium titanate, strontium titanate and strontium bismuth titanate, among others.

The thickness of the insulating layer 663 is variable depending on the dielectric constant of the material used and the geometry of the device being fabricated. Typically, the insulating layer 663 has a thickness of about 100 Å to about 1000 Å.

Referring to FIG. 8B, a titanium nitride (TiN) electrode 664 is formed on the insulating layer 663. The titanium nitride (TiN) electrode 664 is formed with a cyclical deposition process described above with respect to FIGS. 3-4. The thickness of the titanium nitride electrode 664 is typically about 100 Å to about 1000 Å.

After the titanium nitride (TiN) electrode 664 is formed, the metal-insulator-metal (MIM) trench capacitor is completed by filling the trench 659 with, for example, a polysilicon layer 667. The polysilicon layer 667 may be formed using conventional deposition techniques. For example, the polysilicon layer 667 may be deposited using a chemical vapor deposition (CVD) process in which silane (SiH₄) is thermally decomposed to form polysilicon at a temperature between about 550° C. and 700° C.

While foregoing is directed to the preferred embodiment of the present invention, other and further embodiments of the invention may be devised without departing from the basic scope thereof, and the scope thereof is determined by the claims that follow.

1. A method of forming a TiN layer, comprising:
introducing a substrate into a process environment having a temperature of about 350° C. to about 650° C. and a pressure of about 3 torr to about 10 torr;
establishing a carrier gas flow in the process environment;
providing titanium tetrachloride to the process environment at a flow rate of 50-150 mg/ml for a duration of about 50 to about 150 milliseconds;
adsorbing the titanium tetrachloride on the substrate;
providing ammonia gas to the process environment at a flow rate of about 300 sccm to about 2000 sccm for a duration of about 50 to about 250 milliseconds;
adsorbing the ammonia gas onto the substrate, wherein a TiN film is formed on the substrate; and
repeating the providing and adsorbing steps until a desired thickness of the TiN film is formed.

2. The method of claim 1, wherein the carrier gas is helium (He), argon (Ar), nitrogen (N₂) or hydrogen (H₂).

3. The method of claim 1, wherein the carrier gas is provided at an sccm of about 300 to about 3000.

4. The method of claim 1, wherein the titanium chloride is provided at a flow rate of 100 mg/ml and a duration of 50-100 milliseconds.

5. The method of claim 4, wherein the titanium chloride is provided at a duration of 75 milliseconds.

6. The method of claim 1, wherein the ammonia gas is provided at an sccm of about 400 to about 1000.

7. The method of claim 6, wherein the ammonia gas is provided at an sccm of about 500 to about 700.

8. The method of claim 1, wherein the ammonia gas is provided at a duration of about 100 to about 200 milliseconds.

9. The method of claim 8, wherein the ammonia gas is provided at a duration of about 125 milliseconds.

10. The method of claim 1, further comprising a purge step before one or both providing steps.

11. The method of claim 10, wherein the purge step comprises pulsing a purge gas into the process environment.

12. The method of claim 11, wherein the purge gas is helium (He), argon (Ar), nitrogen (N₂) or hydrogen (H₂).

13. The method of claim 11, wherein the purge gas is provided at an sccm of about 250-3000.

14. The method of claim 13, wherein the purge gas is provided at an sccm of about 500-2550.

15. The method of claim 1, wherein the temperature of the process environment is about 450° C. to about 500° C.

16. The method of claim 1, wherein the pressure of the process environment is about 5 torr.

17. A titanium-derived TiN film with a resistivity of less than 150 μΩ-cm.

18. The titanium-derived TiN film of claim 17, deposited at a heater temperature of less than about 630° C.

19. A titanium-derived TiN film with a chlorine content of less than about 1.5%.

20. The titanium-derived TiN film of claim 19, deposited at a heater temperature of less than about 670° C.

21. The titanium-derived TiN film of claim 19 with a chlorine content of less than about 1.2%.

22. The titanium-derived TiN film of claim 21, deposited at a heater temperature of less than about 670° C.

23. A method of forming a TiN layer, comprising:
introducing a substrate into a process environment of about 450° C. to about 500° C. and a pressure of about 5 torr;
establishing a carrier gas flow at a sccm of about 300-3000 in the process environment;
providing titanium tetrachloride to the process environment at a flow rate of 50-150 mg/ml for a duration of about 50 to about 150 milliseconds;
adsorbing the titanium tetrachloride on the substrate;
pulsing a first purge gas into the process environment at an sccm of about 250 to about 3000;
providing ammonia gas to the process environment at a flow rate of 50-150 mg/ml for a duration of about 50 to about 250 milliseconds;
adsorbing the ammonia gas onto the substrate, wherein a TiN film is formed on the substrate;
pulsing a second purge gas at an sccm of about 250-3000 into the process environment; and
repeating the providing and adsorbing steps until a desired thickness of the TiN film is formed.

24. The method of claim 23, wherein the carrier gas is helium (He), argon (Ar), nitrogen (N₂) or hydrogen (H₂).

25. The method of claim 24 wherein the purge gas is helium (He), argon (Ar), nitrogen (N₂) or hydrogen (H₂).
